(19) United States
(12) Patent Application Publication
(10) Pub. No.: US 2026/0045941 A1
(43) Pub. Date: Feb. 12, 2026

(54) CONTROLLER, TARGET, AND COMMUNICATIONS SYSTEM

(71) Applicant: ROHM Co., Ltd., Kyoto (JP)

(72) Inventor: Kiminobu Sato, Kyoto (JP)

(73) Assignee: ROHM Co., Ltd., Kyoto (JP)

(21) Appl. No.: 19/286,251

(22) Filed: Jul. 31, 2025

(30) Foreign Application Priority Data
Aug. 9, 2024 (JP) 2024-133982

(51) Int. Cl. H03K 5/01

(52) U.S. Cl. CPC H03K 5/01

(57) ABSTRACT

A controller includes a clock signal generation circuit configured to generate a clock signal, and a first pulse signal generation circuit configured to generate a first pulse signal that has the same frequency as the clock signal and in which one of a rising edge or a falling edge is synchronized with the clock signal. The first pulse signal generation circuit is configured to adjust a timing of the other of the rising edge or the falling edge of each of cycles of the first pulse signal, according to content of each of data of a first data transmission.

### CROSS-REFERENCE TO RELATED APPLICATION

This application claims the priority benefits of Japanese application no. 2024-133982, filed on Aug. 9, 2024. The entirety of the above-mentioned patent application is hereby incorporated by reference herein and made a part of this specification.

### BACKGROUND

### Technical Field

The disclosure relates to a controller, a target, and a communications system.

### Description of Related Art

Conventionally, communication in which clock information and data are transmitted by separate signals is known (for example, see Patent Literature 1 (Japanese Patent Application Laid-Open No. 2022-144020)).

In communication in which clock information and data are transmitted by separate signals, a first terminal connected to a first signal line that transmits a signal including clock information and a second terminal connected to a second signal line that transmits a signal including data are required to be provided in each of a transmitting device and a receiving device. However, an increase in the number of terminals invites an increase in cost, and therefore, it is desirable that the increase in the number of terminals is small.

### SUMMARY

A controller disclosed in the specification includes a clock signal generation circuit configured to generate a clock signal, and a first pulse signal generation circuit configured to generate a first pulse signal that has the same frequency as the clock signal and in which one of a rising edge or a falling edge is synchronized with the clock signal. The first pulse signal generation circuit is configured to adjust a timing of the other of the rising edge or the falling edge of each of cycles of the first pulse signal, according to content of each of data of a first data transmission.

A target disclosed in the specification includes a first data reception circuit. The first data reception circuit is configured to recognize one of a rising edge or a falling edge of the first pulse signal sent from a controller as clock information, and to recognize content of each of data of a first data reception according to a timing of the other of the rising edge or the falling edge of each of cycles of the first pulse signal.

A communications system disclosed in the specification includes the controller of the above configuration, and the target of the above configuration.

### BRIEF DESCRIPTION OF THE DRAWINGS

FIG. 1 is a diagram showing a configuration of a power system according to an embodiment.

FIG. 2 is an external perspective view of the sequence IC and the DC/DC converter IC.

FIG. 3 is a conceptual diagram showing an example of the data table stored in the non-volatile memory.

FIG. 4 is a timing chart in the case of the sequence IC transmitting data to the DC/DC converter IC.

FIG. 5 is a timing chart in the case of the DC/DC converter IC transmitting data to the sequence IC.

### DESCRIPTION OF THE EMBODIMENTS

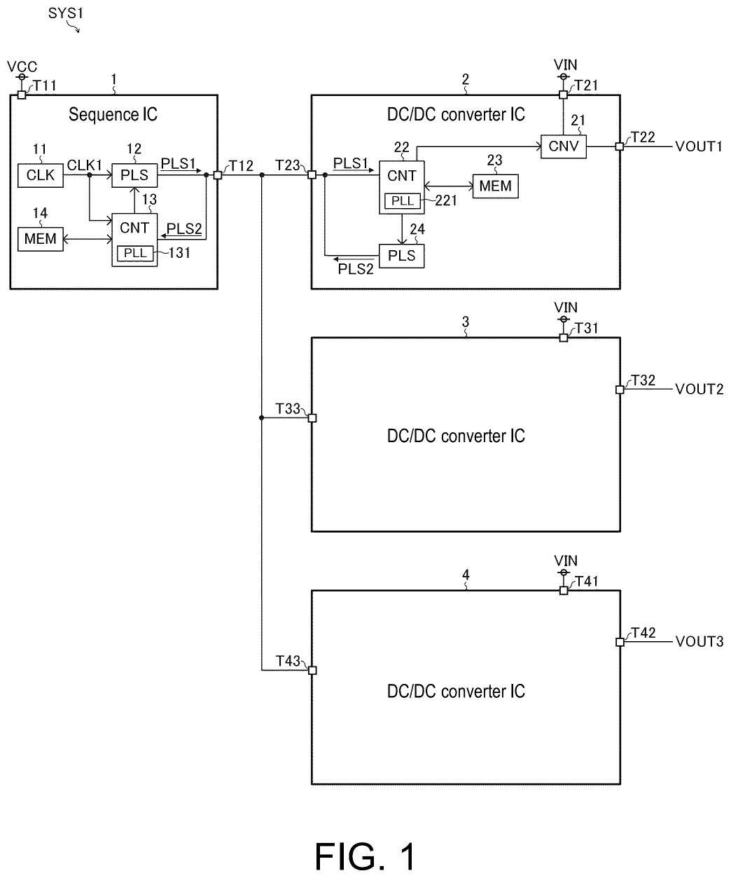

FIG. 1 is a diagram showing a configuration of a power system according to an embodiment. A power system SYS1 is a system configured to generate output voltages VOUT1 to VOUT3 from an input voltage VIN. Moreover, the power system SYS1 is also a communications system configured to communicate clock information and data inside the system. In the communication, open-drain type Input Output (IO) signal control is executed.

The power system SYS1 include a sequence Integrated Circuit (IC) 1, and Direct Current (DC)/DC converter ICs 2 to 4. Note that in the embodiment, the number of DC/DC converter ICs is four, but may also be a multiple number other than four.

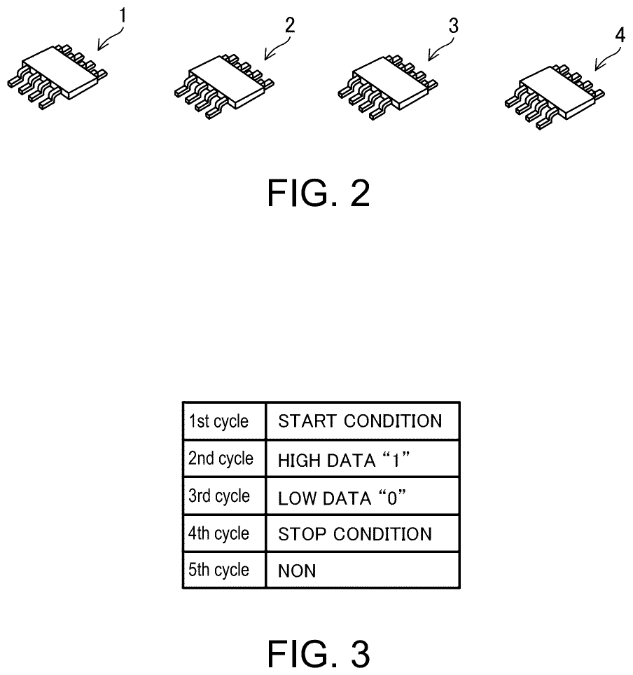

FIG. 2 is an external perspective view of the sequence IC 1 and the DC/DC converter ICs 2 to 4. Each of the sequence IC 1 and the DC/DC converter ICs 2 to 4 is an electronic component formed by encapsulating a semiconductor integrated circuit chip in a housing (package) configured with resin. Multiple terminals are exposed and provided on the housing of each of the sequence IC 1 and the DC/DC converter ICs 2 to 4. Note that the number of terminals of the sequence IC 1 and the DC/DC converter ICs 2 to 4, and the appearance of the sequence IC 1 and the DC/DC converter ICs 2 to 4, are merely illustrative.

As shown in FIG. 1, the sequence IC 1 includes a clock signal generation circuit 11, a first pulse signal generation circuit 12, a control circuit 13, a non-volatile memory 14, and terminals T11 and T12. The sequence IC 1 is driven by a power supply voltage VCC applied to the terminal T11.

The clock signal generation circuit 11 generates a clock signal CLK1. The clock signal generation circuit 11 is configured by, for example, an oscillator. The clock signal CLK1 generated by the clock signal generation circuit 11 is supplied to the first pulse signal generation circuit 12 and the control circuit 13.

The first pulse signal generation circuit 12 generates a first pulse signal PLS1 from the clock signal CLK1. The first pulse signal PLS1 generated by the first pulse signal generation circuit 12 is supplied to the DC/DC converter ICs 2 to 4 via the terminal T12.

The first pulse signal PLS1 is a signal that has the same frequency as the clock signal CLK1 and of which a rising edge is synchronized with the clock signal CLK1. The first pulse signal generation circuit 12 adjusts the timing of a falling edge of each of cycles of the first pulse signal PLS1, based on an instruction from the control circuit 13. More specifically, the first pulse signal generation circuit 12 adjusts the timing of the falling edge of each of cycles of the first pulse signal PLS1, based on an instruction from the control circuit 13 and according to the content of each of data of first data (data group) to be transmitted.

The control circuit 13 includes a Phase Locked Loop (PLL) circuit 131 built therein. The PLL circuit 131 generates a multiplied clock signal MCLK1 from the clock signal CLK1.

The multiplied clock signal MCLK1 is synchronized with the rising edge of the clock signal CLK1. Also, in the embodiment, the frequency of the multiplied clock signal MCLK1 is five times the frequency of the clock signal CLK1.

The non-volatile memory 14 non-volatilely stores a data table shown in FIG. 3. The data table shown in FIG. 3 shows the correspondence between in which cycle of the multiplied clock signal MCLK1, from the rising edge of the first pulse signal PLS1, the falling edge of the first pulse signal PLS1 appears, and the content of data. Furthermore, the data table shown in FIG. 3 also shows the correspondence between in which cycle of the multiplied clock signal MCLK1, from the rising edge of the second pulse signal PLS2 to be described later, the falling edge of the second pulse signal PLS2 appears, and the content of data.

Moreover, in the embodiment, the types of data are five types: “start condition (a signal showing the start of communication)”, “high level digital value”, “low level digital value”, “stop condition (a signal showing the end of communication)”, and “NON (a signal showing no data transmission from the sequence IC)”, but the number of data types is merely an example, and the content of each of the data types is also merely an example. The frequency of the multiplied clock signal MCLK1 is set according to the number of data types. An array of “high level digital values” and “low level digital values” expresses addresses, sequence control content, status notification content, etc. The sequence control content includes commands, etc. The status notification content includes normal status notification, abnormal status notification, etc. Note that the protocol of the communication method is not particularly limited.

The control circuit 13 instructs the first pulse signal generation circuit 12 on the timing of the falling edge of each of cycles of the first pulse signal PLS1, based on the content of each of data of the first data transmission (the data group to be transmitted), the multiplied clock signal MCLK1, and the data table stored in the non-volatile memory 14.

The sequence IC 1 with the above configuration can transmit clock information (the rising edge of the first pulse signal PLS1) and data using the first pulse signal PLS1 (a single signal). Therefore, the sequence IC 1 can reduce the number of terminals.

The DC/DC converter IC 2 includes terminals T21 to T23. The DC/DC converter IC 3 includes terminals T31 to T33. The DC/DC converter IC 4 includes terminals T41 to T43.

The terminal T23 of the DC/DC converter IC 2, the terminal T33 of the DC/DC converter IC 3, and the terminal T43 of the DC/DC converter IC 4 are connected to the terminal T12 of the sequence IC 1 by a signal line.

The DC/DC converter IC 2 converts the input voltage VIN applied to the terminal T21 to the output voltage VOUT1, and outputs the output voltage VOUT1 from the terminal T22. The DC/DC converter IC 3 converts the input voltage VIN applied to the terminal T31 to the output voltage VOUT2, and outputs the output voltage VOUT2 from the terminal T32. The DC/DC converter IC 4 converts the input voltage VIN applied to the terminal T41 to the output voltage VOUT3, and outputs the output voltage VOUT3 from the terminal T42.

Since the internal configurations of the DC/DC converter ICs 2 to 4 are similar, the internal configuration of the DC/DC converter IC 2 is described here as a representative example.

The DC/DC converter IC 2 includes a conversion circuit 21, a control circuit 22, a non-volatile memory 23, and a second pulse signal generation circuit 24.

The conversion circuit 21 converts the input voltage VIN to the output voltage VOUT1. In addition, a part of the conversion circuit 21 (for example, an inductor, an output capacitor, etc.) may be provided outside the DC/DC converter IC 2. In the case of a part of the conversion circuit 21 being provided outside the DC/DC converter IC 2, for example, a switch voltage on a square wave may be output from the terminal T22 instead of the output voltage VOUT1, which is a DC voltage.

The control circuit 22 recognizes the rising edge of the first pulse signal PLS1 sent from the sequence IC 1 as clock information. Also, the control circuit 22 recognizes the content of each of data of the received first data (data group) based on the timing of the falling edge of each of cycles of the first pulse signal PLS1.

The control circuit 22 includes a PLL circuit 221 built therein. The PLL circuit 221 generates a multiplied pulse signal MPLS1 from the first pulse signal PLS1.

The multiplied pulse signal MPLS1 is synchronized with the rising edge of the first pulse signal PLS1. Also, in the embodiment, the frequency of the multiplied pulse signal MPLS1 is five times the frequency of the first pulse signal PLS1.

The non-volatile memory 23 non-volatilely stores the data table shown in FIG. 3. The data table shown in FIG. 3 shows the correspondence between in which cycle of the multiplied pulse signal MPLS1, from the rising edge of the first pulse signal PLS1, the falling edge of the first pulse signal PLS1 appears, and the content of data. Moreover, the data table shown in FIG. 3 also shows the correspondence between in which cycle of the multiplied pulse signal MPLS1, from the rising edge of the second pulse signal PLS2 to be described later, the falling edge of the second pulse signal PLS2 appears, and the content of data.

The second pulse signal generation circuit 24 sets the second pulse signal PLS2 as a signal fixed to a HIGH level and outputs the signal fixed to the HIGH level, excluding a period from completion of data transmission from the sequence IC 1 until start of next data transmission from the sequence IC 1.

The control circuit 22 controls the conversion circuit 21 based on the received first data (data group). For example, if an output stop is instructed in response to the reception of the first data, the control circuit 22 stops the operation of the conversion circuit 21.

The DC/DC converter IC 2 of the above configuration can receive clock information (the rising edge of the first pulse signal PLS1) and data using the first pulse signal PLS1 (a single signal). Therefore, the DC/DC converter IC 2 can reduce the number of terminals.

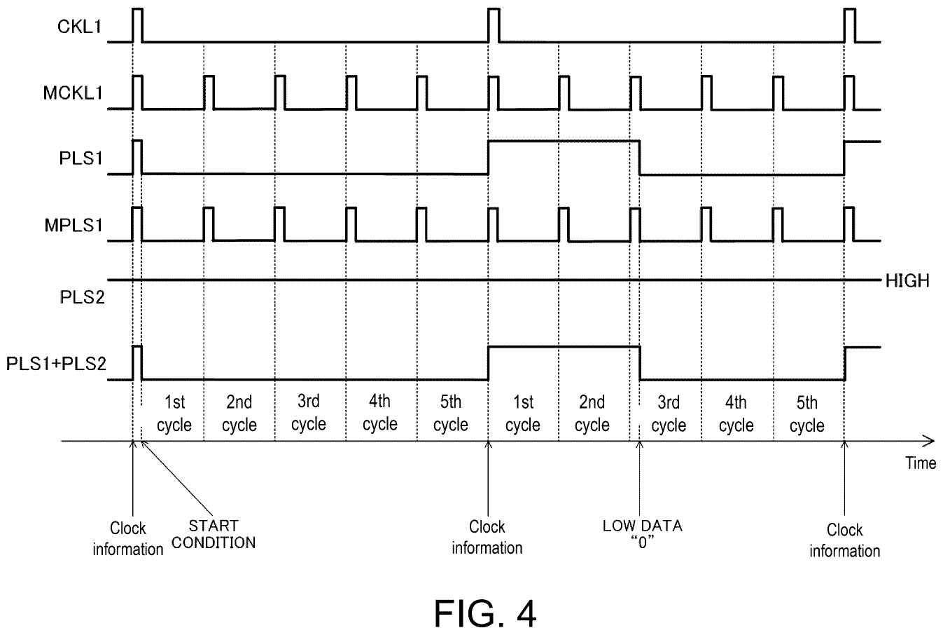

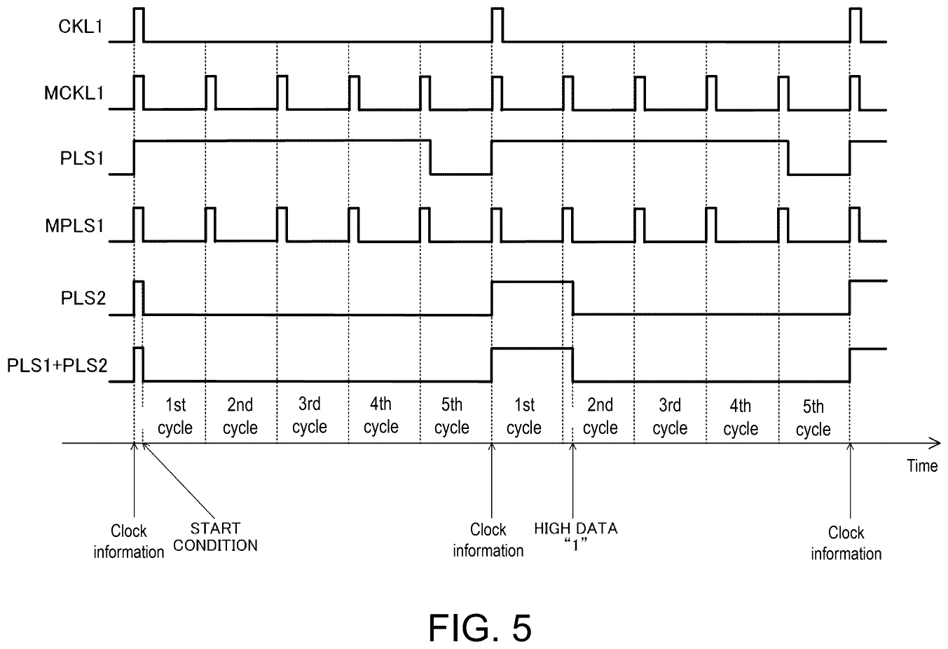

As described above, in the case of the first data (data group) being transmitted from the sequence IC 1 and received by the DC/DC converter IC 2, the waveform of each of the signals is as shown in the timing chart of FIG. 4. Additionally, PLS1+PLS2 shown in FIG. 4 and FIG. 5 to be described later represents a composite signal of the first pulse signal PLS1 and the second pulse signal PLS2, which constitutes the actual communications signal transmitted between the terminal T12 and the terminals T23, T33, and T43.

Furthermore, in the power system SYS1, bidirectional communication is enabled. Specifically, data transmission from the DC/DC converter IC 2 to the sequence IC 1 is feasible. The DC/DC converter IC 2 is capable of transmitting data to the sequence IC 1 during the period from the completion of data transmission from the sequence IC 1 until start of next data transmission from the sequence IC 1.

In response to data transmission from the DC/DC converter IC 2 to the sequence IC 1 being performed, the second pulse signal generation circuit 24 generates the second pulse signal PLS2 from the first pulse signal PLS1. The second pulse signal PLS2 generated by the second pulse signal generation circuit 24 is supplied to the sequence IC 1 via the terminal T23.

In response to data transmission from the DC/DC converter IC 2 to the sequence IC 1 being performed, the second pulse signal PLS2 is a signal having the same frequency as the first pulse signal PLS1, and of which rising edge is synchronized with the first pulse signal PLS1. The second pulse signal generation circuit 24 adjusts the timing of a falling edge of each of cycles of the second pulse signal PLS2, based on an instruction from the control circuit 22. More specifically, the second pulse signal generation circuit 24 adjusts the timing of the falling edge of each of cycles of the second pulse signal PLS2, based on an instruction from the control circuit 22 and according to the content of each of data of second data (data group) to be transmitted.

The control circuit 13 of the sequence IC 1 recognizes the content of each of data of the received second data (data group) based on the timing of the falling edge of each of cycles of the second pulse signal PLS2.

As described above, in the case of the second data (data group) being transmitted from the DC/DC converter IC 2 and received by the sequence IC 1, the waveform of each of the signals is as shown in the timing chart of FIG. 5.

### Others

The above-described embodiment is to be considered in all respects as illustrative and not restrictive, and the technical scope of the disclosure is indicated not by the description of the above-described embodiment but by the claims, and it is to be understood that all modifications that come within the meaning and scope equivalent to the claims are intended to be included.

For example, instead of the sequence IC, a Power Management Integrated Circuit (PMIC) that incorporates multiple DC/DC converters may be used. Note that the DC/DC converter provided outside the PMIC and performing communication with the PMIC may be singular or multiple.

The communication described in the above-described embodiment may also be used in devices, equipment, systems, etc. other than the power system.

In the above-described embodiment, the rising edge of the first pulse signal PLS1 has been synchronized with the clock signal CLK1, but the falling edge of the first pulse signal PLS1 may also be synchronized with the clock signal CLK1.

### Additional Notes

Additional notes are provided regarding the disclosure for which specific configuration examples have been shown in the above-described embodiment.

A controller (1) of the disclosure includes: a clock signal generation circuit (11) configured to generate a clock signal; and a first pulse signal generation circuit (12) configured to generate a first pulse signal that has the same frequency as the clock signal and in which one of a rising edge or a falling edge is synchronized with the clock signal. The first pulse signal generation circuit is a configuration (first configuration) that is configured to adjust a timing of the other of the rising edge or the falling edge of each of cycles of the first pulse signal according to content of each of data of a first data transmission.

The controller of the first configuration described above can transmit clock information (one of the rising edge or the falling edge of the first pulse signal) and data using the first pulse signal (a single signal). Therefore, the controller can reduce the number of terminals.

In the controller of the first configuration described above, it may be a configuration (second configuration) that includes a second data reception circuit (13) configured to recognize content of each of data of a second data reception based on a timing of the other of a rising edge or a falling edge of each of cycles of a second pulse signal sent from a target (2, 3, 4).

The target (2, 3, 4) of the disclosure includes a first data reception circuit (22), and the first data reception circuit is a configuration (third configuration) that is configured to: recognize one of a rising edge or a falling edge of a first pulse signal sent from the controller (1) as clock information; and recognize content of each of data of a first data reception based on a timing of the other of the rising edge or the falling edge of each of cycles of the first pulse signal.

The target of the third configuration described above can receive clock information and data using the first pulse signal (a single signal). Therefore, the target can reduce the number of terminals.

In the target of the third configuration described above, it may be a configuration (fourth configuration) that includes a multiplied pulse signal generation circuit (221) configured to generate a multiplied pulse signal that is synchronized with one of the rising edge or the falling edge of the first pulse signal and of which frequency is a multiple of the frequency of the first pulse signal. The first data reception circuit is configured to recognize content of each of data of the first data reception according to in which cycle of the multiplied pulse signal, from one of the rising edge or the falling edge of the first pulse signal, the other of the rising edge or the falling edge of each of cycles of the first pulse signal appears.

In the target of the above-mentioned third or fourth configuration, it includes a second pulse signal generation circuit (24) configured to generate a second pulse signal that has the same frequency as the first pulse signal and in which one of a rising edge or a falling edge is synchronized with the first pulse signal, and the second pulse signal generation circuit may be a configuration (fifth configuration) that is configured to adjust a timing of the other of the rising edge or the falling edge of each of cycles of the second pulse signal according to content of each of data of a second data transmission.

The communications system (SYS1) of the disclosure is a configuration (sixth configuration) that includes the controller of the first or second configuration described above and the target of any of the third to fifth configurations described above.

In the communications system of the sixth configuration described above, a type of the each of data may be a configuration (seventh configuration) that includes sequence control content and status notification content.

What is claimed is:

1. A controller, comprising:
a clock signal generation circuit, configured to generate a clock signal; and
a first pulse signal generation circuit, configured to generate a first pulse signal, the first pulse signal having the same frequency as the clock signal, and one of a rising edge or a falling edge of the first pulse signal being synchronized with the clock signal, and
the first pulse signal generation circuit being configured to adjust a timing of the other of the rising edge or the falling edge of each of cycles of the first pulse signal, according to content of each of data of a first data transmission.

2. The controller according to claim 1, comprising a second data reception circuit, configured to recognize content of each of data of a second data reception, based on a timing of the other of a rising edge or a falling edge of each of cycles of a second pulse signal sent from a target.

3. A target, comprising:
a first data reception circuit, and
the first data reception circuit being configured to recognize one of a rising edge or a falling edge of a first pulse signal sent from a controller as clock information, and to recognize content of each of data of a first data reception based on a timing of the other of the rising edge or the falling edge of each of cycles of the first pulse signal.

4. The target according to claim 3, comprising:
a multiplied pulse signal generation circuit, configured to generate a multiplied pulse signal that is synchronized with one of the rising edge or the falling edge of the first pulse signal and of which frequency is a multiple of the first pulse signal, and
the first data reception circuit being configured to recognize content of each of data of the first data reception according to in which cycle of the multiplied pulse signal, from one of the rising edge or the falling edge of the first pulse signal, the other of the rising edge or the falling edge of each of cycles of the first pulse signal appears.

5. The target according to claim 3, comprising:
a second pulse signal generation circuit, configured to generate a second pulse signal, the second pulse signal having the same frequency as the first pulse signal, and one of a rising edge or a falling edge of the second pulse signal being synchronized with the first pulse signal, and
the second pulse signal generation circuit being configured to adjust a timing of the other of the rising edge or the falling edge of each of cycles of the second pulse signal, according to content of each of data of a second data transmission.

6. A communications system, comprising: the controller according to claim 1; and
a target, comprising:
a first data reception circuit, and
the first data reception circuit being configured to recognize one of a rising edge or a falling edge of a first pulse signal sent from a controller as clock information, and to recognize content of each of data of a first data reception based on a timing of the other of the rising edge or the falling edge of each of cycles of the first pulse signal.

7. The communications system according to claim 6, wherein types of the each of data include sequence control content and status notification content.
